(19) United States
(12) Patent Application Publication
(10) Pub. No.: US 2008/0197514 A1
(43) Pub. Date: Aug. 21, 2008

(54) DIE COAT PERIMETER TO ENHANCE SEMICONDUCTOR RELIABILITY

(76) Inventor: Thomas Goida, Windham, NH (US)

Correspondence Address: GAUTHIER & CONNORS, LLP, 225 FRANKLIN STREET, SUITE 2300, BOSTON, MA, 02110, US

(21) Appl. No.: 11/675,806

(22) Filed: Feb. 16, 2007

(51) Int. Cl. H01L 23/29; H01L 21/00; H01L 23/24

(52) U.S. Cl. 257/788; 438/127; 257/E23.117; 257/E21.001

(57) ABSTRACT

A semiconductor packaging stress relief technique with enhanced reliability. Reliability is enhanced over conventional post wirebond assembly die coating processes by forming a peripheral wall on the semiconductor die isolating the stress sensitive area from remaining area in the semiconductor die, and depositing die coat material constraining the flow of the die coat material in the stress sensitive area of the semiconductor die. The peripheral wall, by constraining flow of the die coat material, prevents stress on the package bond wires caused by mismatch in coefficient of thermal expansion between the die coat and the package bond wires which are encased in the plastic molding compound.

### BACKGROUND OF THE INVENTION

1. Field of Invention

The present invention relates generally to the field of semiconductor packaging. More specifically, the present invention is related to a method for enhancing the reliability of stress relief coatings commonly used in plastic semiconductor packaging.

2. Discussion of Prior Art

The performance of many semiconductor devices can be negatively impacted by the plastic packaging process. The typical plastic packaging process results in direct physical contact of the semiconductor device with the plastic mold compound. This contact can cause a fluctuation in the performance and reliability of the product due to thermal coefficient of expansion mismatches between the silicon semiconductor device and the plastic package molding compound. Silicone die coats are excellent stress relief materials for use in semiconductor packages. Unfortunately, silicone die coats when in contact with package bond wires stress those bond wires during thermal cycles due to mismatched coefficient of thermal expansions (CTEs).

Specifically, in high-performance semiconductor packaging structures, a temperature coefficient mismatch occurs due to the uneven expansion of the plastic molding compound as compared to the silicon die whereby localized stress caused by the expansion affects resistor shift values.

FIG. 1 illustrates a prior art scenario where package stress affects the value of on-chip resistors (piezo resistance affect). In this scenario, plastic molding compound 106 imparts package stress 104 which causes fluctuation in the value of the on-chip resistor 102. Such a fluctuation in the resistance value causes fluctuation in the performance and reliability of the product.

FIG. 2 illustrates a prior art solution to address such fluctuation in performance via the use of a silicone die coat (e.g., silicone gel). According to this solution, a silicone die coat (e.g., silicone gel) 202 is used to prevent direct contact with mold compound thereby improving performance and reliability. The application of silicone gel on top of the die prevents the mold compound from getting in direct contact with stress sensitive areas of the die surface for non-micromachined products. However, even the prior art solution illustrated in FIG. 2 suffers from various pitfalls that affect the performance and reliability of the product.

FIG. 3 illustrates the problem with the use of a silicone die coat, such as silicone gel. The silicone gel has a CTE that is much greater than the plastic molding compound. Table 1, shown below, shows an example of such a variation in CTEs between a silicone gel die coat and an epoxy molding compound.

| | Tg | CTE |
|---|---|---|
| Silicone Gel Die Coat | −100° C. | 262 |
| Epoxy Molding Compound | +135° C. | 15 |

During temperature exposure such as solder reflow, a large amount of stress is placed on the ball bond and ball bond neck, as shown by arrows 302.

FIGS. 4a-b illustrates the effects of stress on the structure of FIG. 3. FIG. 4a illustrates a scenario where a “lift” happens at the ball bond due to the stress caused by the variation in the CTEs. FIG. 4b illustrates another scenario involving the potential for wire breakage (i.e., fracture in wire) due to the stress caused by the variation in the CTEs.

The patent to Carl Roberts Jr. (U.S. Pat. No. 5,026,667) teaches the production of integrated circuit chips with reduced stress effects. The '667 patent addresses the need to keep die coating material away from the bond wires. Roberts' invention, while effective in terms of both stress relief and improved package reliability, is limited in terms of the stress buffer coatings which can be used.

Another method to reduce die surface stress is by the use of a polymer coating such as polyimide applied on the entire wafer via lithography processes to create openings for processes such as wire bonding and wafer saw. The paper to Schukert et al. titled “Polyimide Stress Buffers in IC Technology” reviews the properties of such a polyimide layer as a stress relief buffer layer for use with integrated circuits packaged in plastic. FIG. 4c illustrates the prior art solution of wafer level applied coating 402. Wafer level coatings, as shown in FIG. 4c, are typically limited in terms of coating thicknesses and limited in terms of materials which can be used. Silicone gels applied during the assembly process are far superior in terms of their ability to relieve package stress as compared to wafer level applied polyimides.

Whatever the precise merits, features, and advantages of the above cited references, none of them achieves or fulfills the purposes of the present invention.

### SUMMARY OF THE INVENTION

The present invention, therefore, provides a method to enhance reliability of a semiconductor package, wherein the method comprises: (a) constructing a peripheral wall on the semiconductor die, said peripheral wall isolating a stress sensitive area from remaining area of the semiconductor die; and (b) depositing die coat material on the remaining area of the semiconductor die wherein the peripheral wall constrains the flow of the die coat material in the stress sensitive area of said semiconductor die. The peripheral wall, by constraining flow of the die coat material, prevents stress on the bond wires caused by mismatch in coefficient of thermal expansion between the die coat and the semiconductor die.

In another embodiment, the present invention provides for a method to enhance reliability of a semiconductor package, wherein the method comprises: (a) constructing a polymer dam on the semiconductor die wherein the polymer dam isolates a stress sensitive area from the remaining area of the semiconductor die; and (b) depositing die coat material on the remaining area of the semiconductor die such that the polymer dam constraining flow of the die coat material in said stress sensitive area of said semiconductor die. The peripheral wall, by constraining flow of said die material, prevents stress on the bond wires caused by mismatch in coefficient of thermal expansion between the die coat and the semiconductor die.

The present invention, in one embodiment, provides for a semiconductor package having enhanced reliability comprising: (a) a semiconductor die; (b) a peripheral wall formed on the semiconductor die, wherein the peripheral wall isolates a stress sensitive area from the remaining area of the semiconductor die; (c) a die coat material formed on the remaining area of the semiconductor die, wherein the peripheral wall constrains the flow of the die coat material in the stress sensitive area of the semiconductor die; (d) a molding compound enclosing the semiconductor die with the peripheral wall and die coat material. The peripheral wall, by constraining flow of the die coating material, ensures that the die coat material does not come in contact with the bond wires and minimizes stress caused by mismatch in coefficient of thermal expansion between the die coat and the wirebonds.

The present invention, in another embodiment, provides for a semiconductor package having enhanced reliability comprising: (a) a semiconductor die; (b) a polymer dam formed on the semiconductor die, wherein the peripheral wall isolates a stress sensitive area from the remaining area of the semiconductor die; (c) a die coat material formed on the remaining area of the semiconductor die, wherein the polymer dam constrains the flow of the die coat material in the stress sensitive area of the semiconductor die; (d) a molding compound enclosing the semiconductor die with the polymer dam and die coat material. The polymer dam, by constraining flow of the die material, ensures that the die coat material does not come in contact with the bond wires and therefore minimizes stress caused by mismatch in coefficient of thermal expansion between the die coat and the bond wires of the semiconductor device.

### BRIEF DESCRIPTION OF THE DRAWINGS

FIG. 1 illustrates a prior art scenario where package stress affects the value of on chip resistors.

FIG. 2 illustrates a prior art solution to address fluctuation in performance via the use of a silicone die coat (e.g., silicone gel).

FIG. 3 illustrates the problem with the use of a silicone die coat.

FIGS. 4a-b illustrate the effects of stress on the structure of FIG. 3.

FIG. 4c illustrates the prior art solution of wafer level applied coating.

FIG. 5 illustrates the die coat perimeter that is constructed as per the present invention.

FIG. 6 illustrates another die coat perimeter that is constructed as per the present invention.

FIGS. 7a-d illustrate various examples of semiconductor packaging made according to the principles of the present invention.

FIG. 8 illustrates a final configuration according to an exemplary embodiment of the present invention.

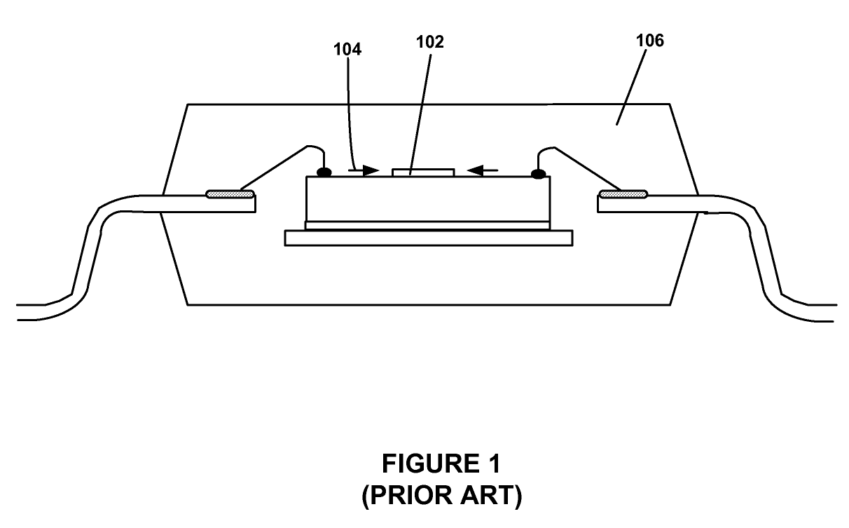

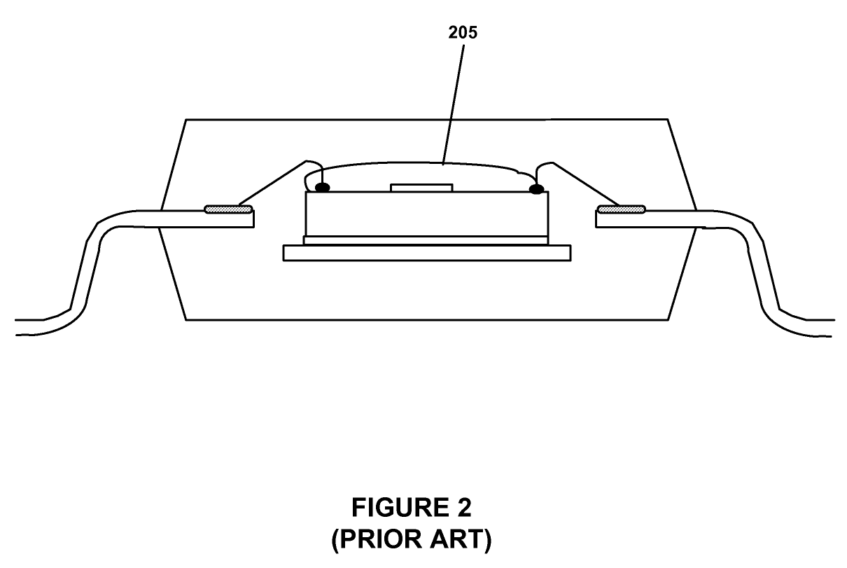

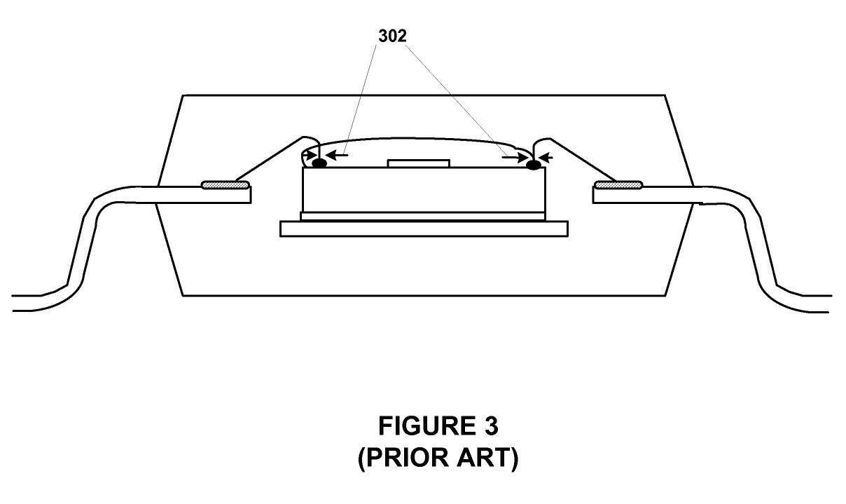

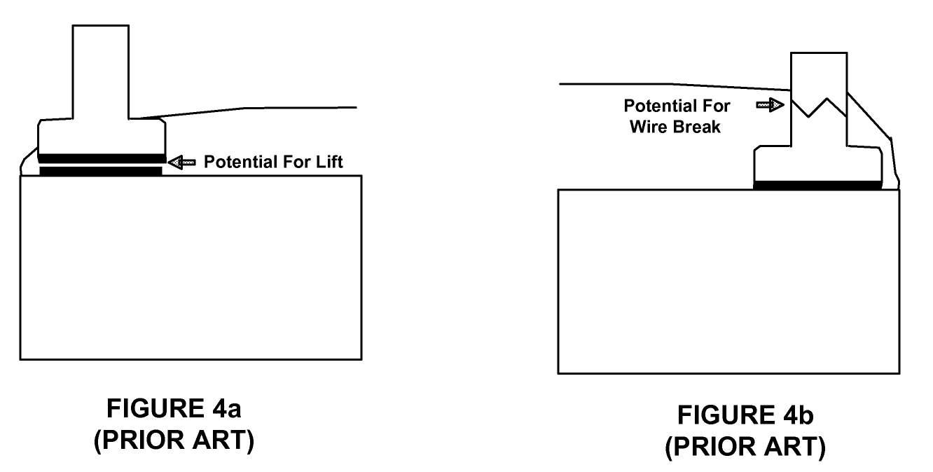

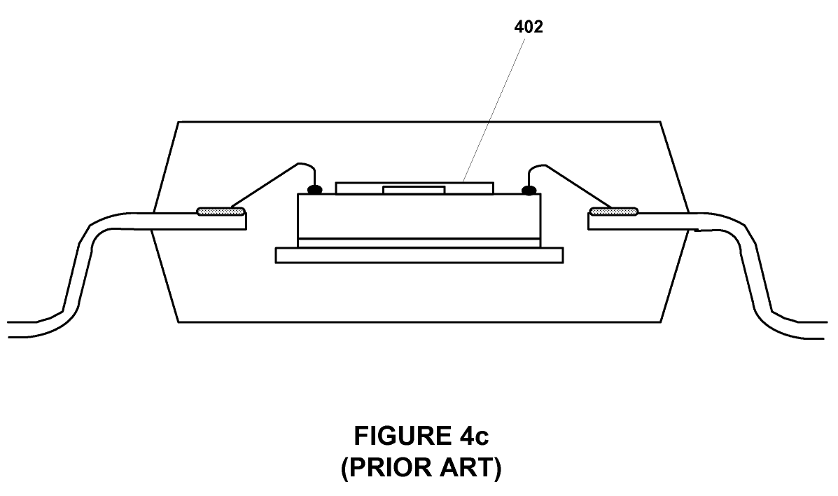

### DESCRIPTION OF THE PREFERRED EMBODIMENTS

While this invention is illustrated and described in a preferred embodiment, the invention may be produced in many different configurations. There is depicted in the drawings, and will herein be described in detail, a preferred embodiment of the invention, with the understanding that the present disclosure is to be considered as an exemplification of the principles of the invention and the associated functional specifications for its construction and is not intended to limit the invention to the embodiment illustrated. Those skilled in the art will envision many other possible variations within the scope of the present invention.

The present invention provides for a method of creating die coat perimeter (such as a dam) to enhance semiconductor reliability. The present invention's construction of a peripheral wall (dam) which constrains the flow of die surface stress relieving die coating materials such as silicone gels or other stress relieving materials to ensure it does not come in contact with the bond wires. In one embodiment, the present invention's wall (dam) is constructed using polymers via conventional photolithography wafer fabrication techniques or with screen printing. Polymer materials may include but not limited to Benzocyclobutene (BCB) or polyimide.

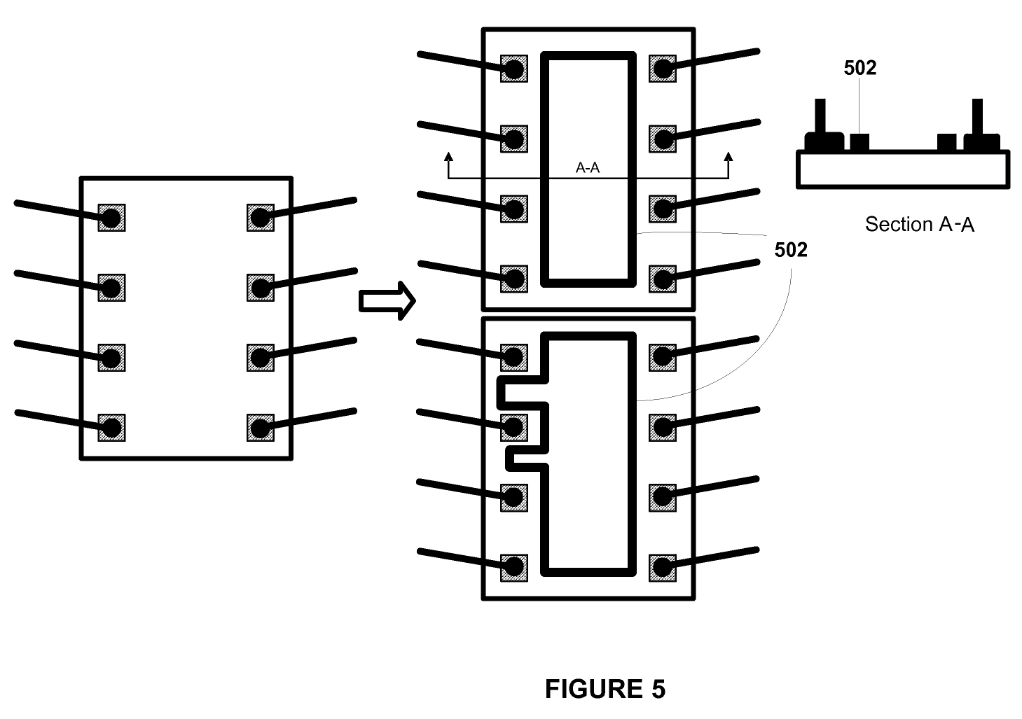

FIG. 5 illustrates the die coat perimeter 502 that is constructed as per the present invention, wherein the coat perimeter 502 comprises a peripheral wall (dam) which constrains the flow of the silicone gel to ensure it does not come in contact with the bond wires. It should be noted that the peripheral wall 502 can be constructed in various shapes.

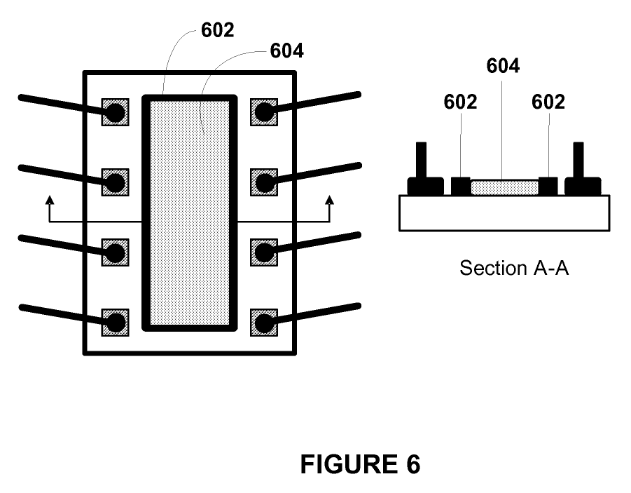

FIG. 6 illustrates a die coat perimeter 602 that is constructed as per the present invention, wherein the coat perimeter 602 comprises peripheral wall (dam) which constrains the flow of the silicone gel to ensure it does not come in contact with the bond wires. After the peripheral wall dam is formed, material 604 such as silicone gel is applied. 604 depicts the silicone gel having been dispensed within the boundary of the damn now providing stress relief to the stress sensitive areas of the die. The cross-section A-A shown in FIG. 6 illustrates how material 604 is constrained within the confines of the peripheral wall (dam) 602. The present invention's construction allows for the flow of the silicone gel to be constrained to a pre-defined area (i.e., defined by the perimeter of the wall) to ensure the gel does not come in contact with the bond wires. In one embodiment, the present invention's wall (dam) is constructed using polymers in wafer fabrication such as BCB or polyimide.

The present invention, therefore, provides a method to enhance reliability of a semiconductor package, wherein the method comprises: (a) selecting a stress sensitive area on a semiconductor die; (b) constructing a peripheral wall on the semiconductor die, said peripheral wall isolating said stress sensitive area from remaining area of the semiconductor die; and (c) depositing die coat material on the remaining area of the semiconductor die wherein the peripheral wall constrains the flow of the die coat material in the stress sensitive area of said semiconductor die. The peripheral wall, by constraining flow of the die coat material, prevents stress caused by mismatch in coefficient of thermal expansion between the die coat and the wirebonded silicon semiconductor device.

In another embodiment, the present invention provides for a method to enhance reliability of a semiconductor package, wherein the method comprises: (a) selecting a stress sensitive area on a semiconductor die; (b) constructing a polymer dam on the semiconductor die wherein the polymer dam isolates the stress sensitive area from the remaining area of the semiconductor die; and (c) depositing die coat material on the remaining area of the semiconductor die such that the polymer dam constraining flow of the die coat material in said stress sensitive area of said semiconductor die. The peripheral wall, by constraining flow of said die material, prevents stress caused by mismatch in coefficient of thermal expansion between the die coat and the wirebonds of the silicon semiconductor device.

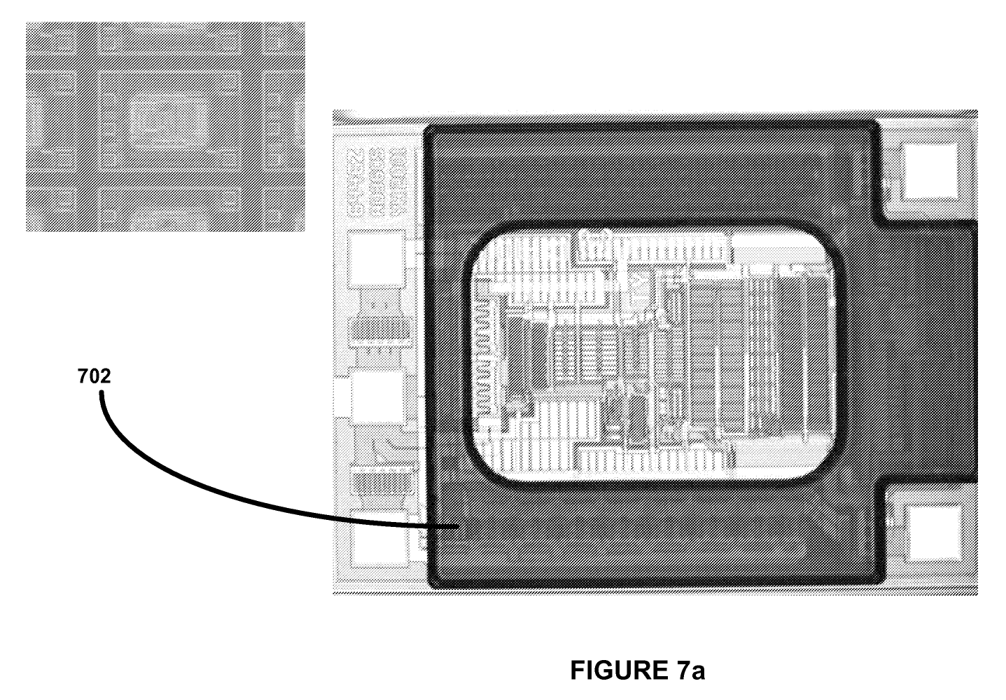

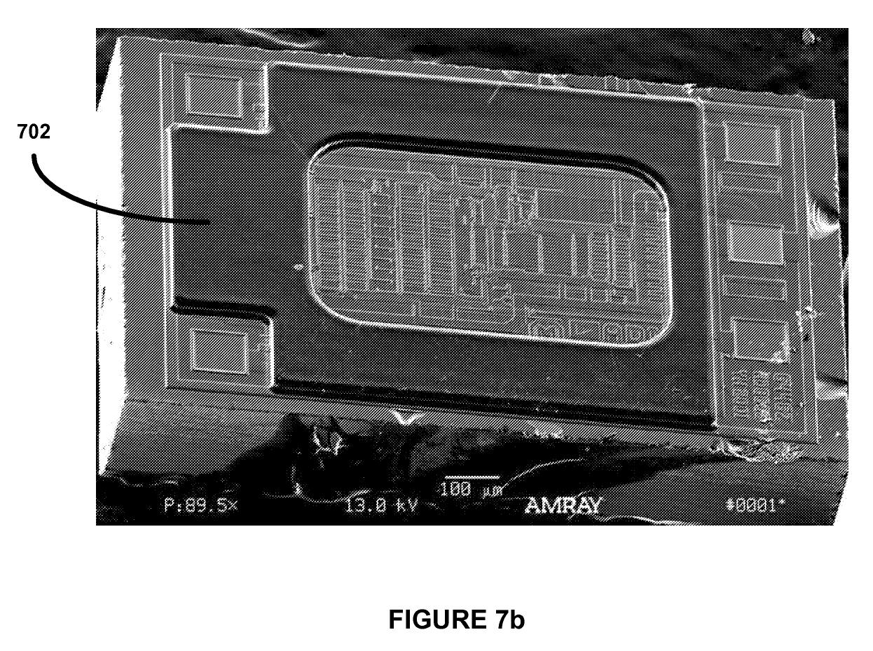

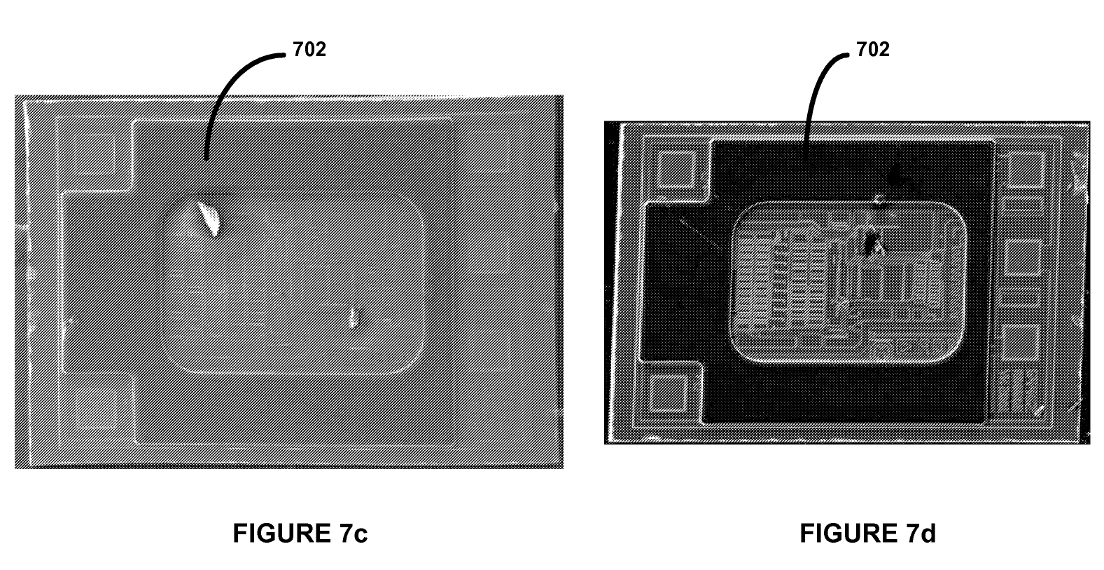

FIGS. 7a-d illustrate various examples of semiconductor packaging made according to the principles of the present invention wherein dam 702 constrains the flow of die coating material (such as silicone gel) into a stress prone region of the die (e.g., areas that have bond wires). FIGS. 7a-d depict the construction of the polymer dam with the stress sensitive portions of the die in the center of the dam.

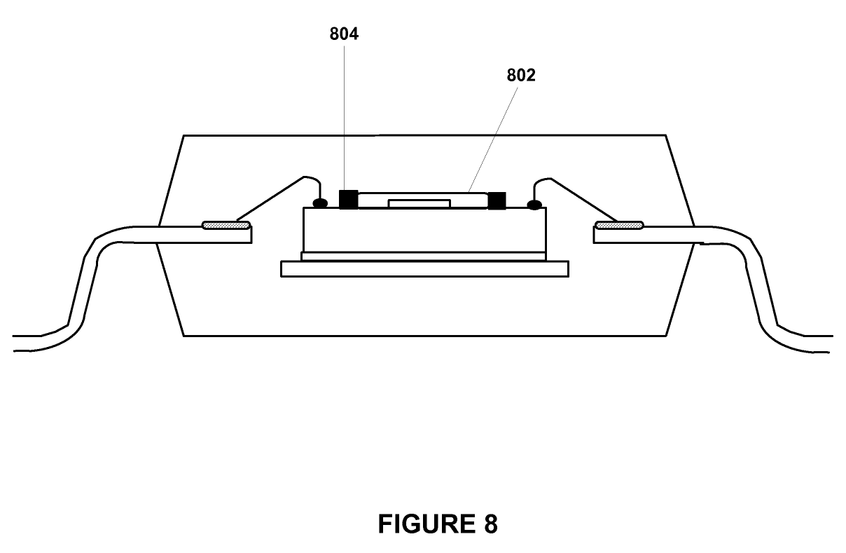

FIG. 8 illustrates a final configuration according to an exemplary embodiment of the present invention. Silicone die coat 802 provides superior stress relief to thin film resistor, while polymer damn 804 restrains coating material away from ball bonds, thereby preventing stress on the bond wires caused by mismatch in coefficient of thermal expansion between the die coat and the semiconductor die.

The present invention, in one embodiment, provides for a semiconductor package having enhanced reliability comprising: (a) a semiconductor die; (b) a peripheral wall formed on the semiconductor die, wherein the peripheral wall isolates a stress sensitive area from the remaining area of the semiconductor die; (c) a die coat material formed on the remaining area of the semiconductor die, wherein the peripheral wall constrains the flow of the die coat material in the stress sensitive area of the semiconductor die; (d) a molding compound enclosing the semiconductor die with the peripheral wall and die coat material. The peripheral wall, by constraining flow of the die material, ensures that the die coat material does not come in contact with the stress sensitive area and minimizes stress caused by mismatch in coefficient of thermal expansion between the die coat and the wirebonds of the silicon semiconductor device.

The present invention, in another embodiment, provides for a semiconductor package having enhanced reliability comprising: (a) a semiconductor die; (b) a polymer dam formed on the semiconductor die, wherein the peripheral wall isolates a stress sensitive area from the remaining area of the semiconductor die; (c) a die coat material formed on the remaining area of the semiconductor die, wherein the polymer dam constrains the flow of the die coat material in the stress sensitive area of the semiconductor die; (d) a molding compound enclosing the semiconductor die with the polymer dam and die coat material. The polymer dam, by constraining flow of the die material, ensures that the die coat material does not come in contact with the stress sensitive area and minimizes stress caused by mismatch in coefficient of thermal expansion between the die coat and the wirebonds of the silicon semiconductor device.

### CONCLUSION

A system and method has been shown in the above embodiments for the effective implementation of a die coat perimeter to enhance semiconductor reliability. While various preferred embodiments have been shown and described, it will be understood that there is no intent to limit the invention by such disclosure, but rather, it is intended to cover all modifications falling within the spirit and scope of the invention, as defined in the appended claims. For example, the present invention should not be limited by the shape of the dam, the type of polymer used to form the peripheral wall, the material used in constructing the dam, or the method used to construct the dam.

1. A method to enhance reliability of a semiconductor package comprising:
(a) constructing a peripheral wall on a semiconductor die, said peripheral wall isolating a stress sensitive area from remaining area of said semiconductor die;
(b) depositing a stress relieving die coat material on said remaining area of said semiconductor die, said peripheral wall constraining flow of said die coat material in said stress sensitive area of said semiconductor die, and
wherein said peripheral wall, by constraining flow of said die coat material, prevents stress caused by mismatch in coefficient of thermal expansion between said die coat and bond wires of the silicon semiconductor die.

2. The method of claim 1, wherein said stress sensitive area is a pre-selected stress sensitive area on said semiconductor die.

3. The method of claim 1, wherein said peripheral wall is formed of polymer.

4. The method of claim 3, wherein said polymer is polyimide.

5. The method of claim 1, wherein said peripheral wall is formed of benzocyclobutene.

6. The method of claim 1, wherein said die coat material is silicone gel.

7. A method to enhance reliability of a semiconductor package comprising:
(a) constructing a polymer dam on a semiconductor die, said polymer dam isolating said stress sensitive area from remainder of said semiconductor die;
(b) depositing die coat material, said polymer dam constraining flow of said die coat material in said stress sensitive area of said semiconductor die, and
wherein said peripheral wall, by constraining flow of said die coat material, prevents stress on bond wires caused by mismatch in coefficient of thermal expansion between said die coat and the bond wires of the semiconductor die.

8. The method of claim 7, wherein said stress sensitive area is a pre-selected stress sensitive area in said semiconductor die.

9. The method of claim 7, wherein said polymer is polyimide.

10. The method of claim 7, wherein said polymer dam is formed of benzocyclobutene.

11. The method of claim 7, wherein said die coat material is silicone gel.

12. A semiconductor package having enhanced reliability comprising:
(a) a semiconductor die;
(b) a peripheral wall formed on said semiconductor die, said peripheral wall isolating a stress sensitive area from remaining area of said semiconductor die;
(c) a die coat material formed on said remaining area of said semiconductor die, said peripheral wall constraining flow of said die coat material in said stress sensitive area of said semiconductor die;
(d) a molding compound enclosing said semiconductor die with said peripheral wall and die coat material, and
said peripheral wall, by constraining flow of said die coating material, ensuring that said die coat material does not come in contact with bond wires and minimizing stress caused by mismatch in coefficient of thermal expansion between said die coat and the bond wires of said semiconductor die.

13. The semiconductor package of claim 12, wherein said peripheral wall is formed of polymer.

14. The semiconductor package of claim 12, wherein said polymer is polyimide.

15. The semiconductor package of claim 12, wherein said peripheral wall is formed of benzocyclobutene.

16. The semiconductor package of claim 12, wherein said die coat material is silicone gel.

17. A semiconductor package having enhanced reliability comprising:
(a) a semiconductor die;
(b) a polymer dam formed on said semiconductor die, said polymer dam isolating a stress sensitive area from remaining area of said semiconductor die;
(c) a die coat material formed on said remaining area of said semiconductor die, said peripheral wall constraining flow of said die coat material in said stress sensitive area of said semiconductor die;
(d) a molding compound enclosing said semiconductor die with said peripheral wall and die coat material, and
said polymer dam, by constraining flow of said die material, ensuring that said die coat material does not come in contact with bond wires and minimizing stress caused by mismatch in coefficient of thermal expansion between said die coat and bond wires of semiconductor device.

18. The semiconductor package of claim 17, wherein said polymer dam is formed of benzocyclobutene.

19. The semiconductor package of claim 17, wherein said die coat material is silicone gel.
